(19) United States
(12) Patent Application Publication
(10) Pub. No.: US 2011/0249414 A1
(43) Pub. Date: Oct. 13, 2011

(54) SYSTEM FOR PLACING ELECTRONIC DEVICES IN A RESTRICTED SPACE OF A PRINTED CIRCUIT BOARD

(76) Inventors: Robert E Krancher, Cypress, TX (US); Scott P. Saunders, Spring, TX (US); Brian D. Ryder, Tomball, TX (US)

(21) Appl. No.: 13/139,740

(22) PCT Filed: Dec. 15, 2008
(86) PCT No.: PCT/US08/86876

§ 371 Date: Jun. 15, 2011

(51) Int. Cl. H05K 5/00; H05K 1/16; H05K 1/18

(52) U.S. Cl. 361/752; 361/761; 174/260

(57) ABSTRACT

A system for placing electronic devices in restricted spaces of a printed circuit board. At least some of the illustrative embodiments are systems comprising a printed circuit board that comprises at least one conductive layer and at least one insulative layer (an outer surface of the printed circuit board defines a first plane), a void within the printed circuit board (the void defines an aperture through the outer surface, the void has at least one side wall at least partially defined by the insulative layer, and the void has a bottom that defines a second plane substantially parallel to the first plane), a first electronic device coupled to the printed circuit board within the void, and a second electronic device coupled to the outer surface, the second electronic device at least partially occludes the aperture.

### BACKGROUND

Mobile computing devices (e.g., laptop or notebook computers, personal digital assistants (PDA), mobile telephones) are getting smaller in size while performing a multitude of functions some of which include recording audio, video, or transmitting and receiving messages. Performing the multitude of functions requires the mobile computing devices to comprise a plurality of electronic devices (e.g., graphics module, memory module) within a limited space.

### BRIEF DESCRIPTION OF THE DRAWINGS

For a detailed description of exemplary embodiments, reference will now be made to the accompanying drawings in which:

FIG. 1 shows a mobile computing system in accordance with some embodiments;

FIG. 2A shows a printed circuit board in accordance with some embodiments;

FIG. 2B shows a cross-sectional view of the printed circuit board in accordance with some embodiments; and

FIG. 3 shows a cross-sectional view of the printed circuit board in accordance with some embodiments.

### NOTATION AND NOMENCLATURE

Certain terms are used throughout the following description and claims to refer to particular system components. As one skilled in the art will appreciate, computer companies may refer to a component by different names. This document does not intend to distinguish between components that differ in name but not function.

In the following discussion and in the claims, the terms “including” and “comprising” are used in an open-ended fashion, and thus should be interpreted to mean “including, but not limited to . . . .” Also, the term “couple” or “couples” is intended to mean either an indirect or direct connection. Thus, if a first device couples to a second device, that connection may be through a direct connection or through an indirect connection via other devices and connections.

### DETAILED DESCRIPTION

The following discussion is directed to various embodiments. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

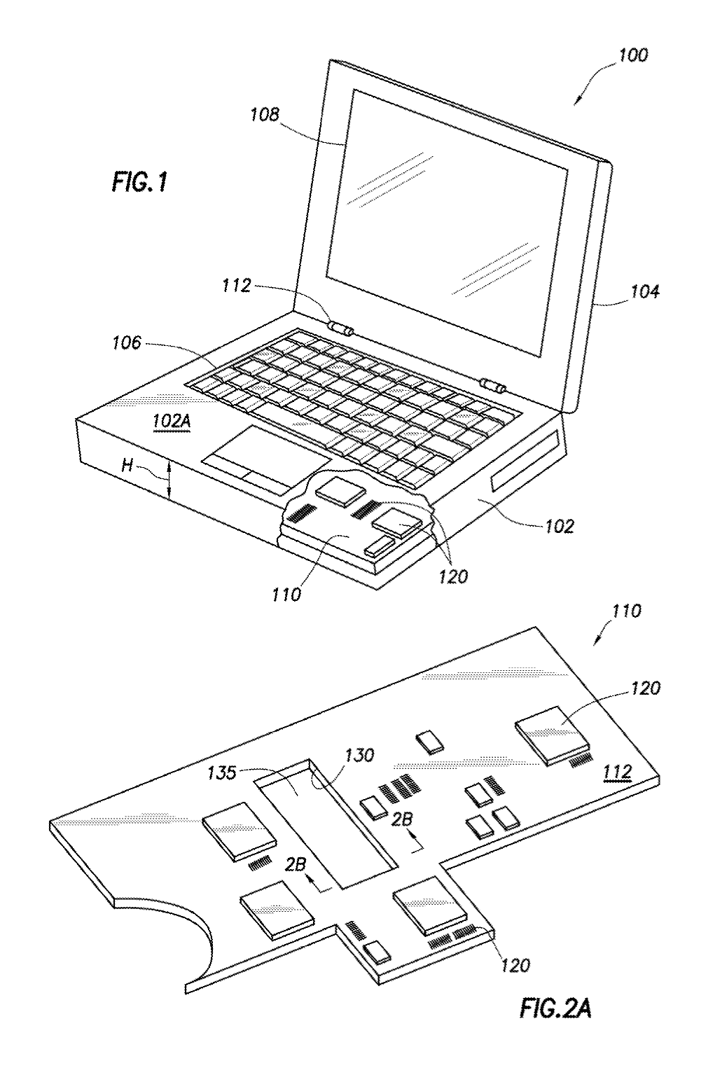

FIG. 1 illustrates a mobile computing system 100 in accordance with at least some embodiments. The mobile computing system comprises a first chassis 102 and a second chassis 104. The first chassis 102 couples to the second chassis by way of a hinge 112. The first chassis 102 comprises a user interface, such as a keyboard 106. So that the information may be conveyed to a user, the second chassis 104 of the mobile computing system 100 comprises a display screen 108.

In at least some embodiments, the mobile computing system 100 comprises one or more printed circuit boards 110 mounted within the mobile computing system 100. In some mobile computing systems, the thickness ‘H’ of the mobile computing system 100 is reduced to produce aesthetically pleasing mobile computing systems 100. However, reducing the thickness ‘H’ also reduces the clearance between the top surface 102A of the chassis 102 and electronic devices 120 coupled to the printed circuit board 110. In some embodiments, reducing the clearance entails the electronic devices 120 to be distributed horizontally across the printed circuit board 110. In accordance with the various embodiments, the printed circuit board 110 for the mobile computing system 100 enables coupling electronic devices 120 where the clearance between the top surface 102A of the chassis 102 and the electronic devices 120 is relatively small.

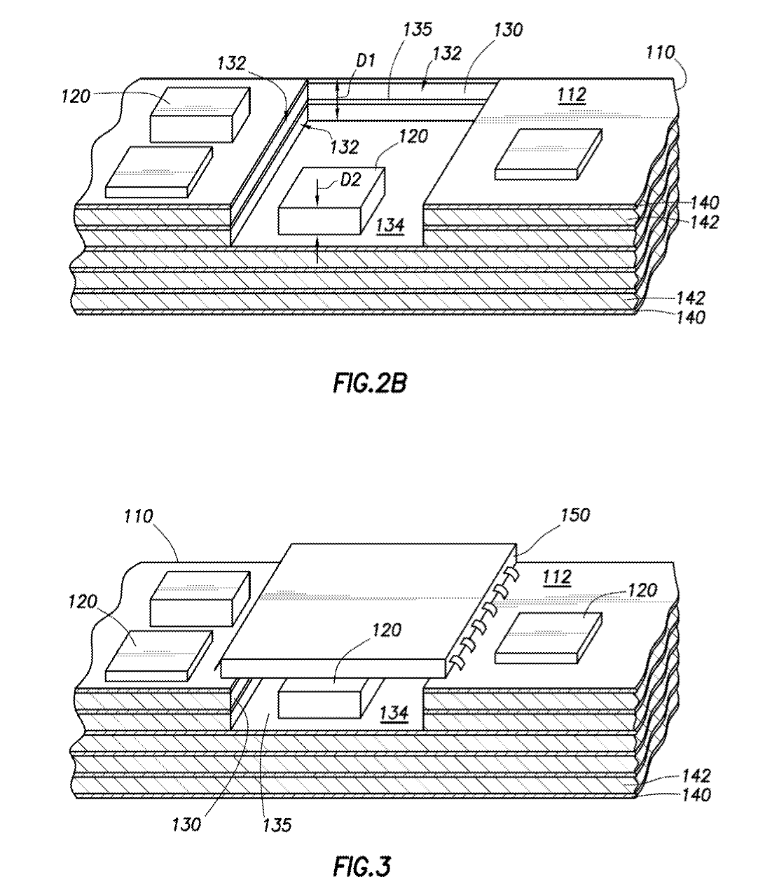

FIG. 2A illustrates the printed circuit board 110 in accordance with at least some embodiments. In the embodiments of FIG. 2A, the printed circuit board 110 comprises a plurality of electronic devices 120 coupled to an outer surface 112 (e.g., by soldering) of the printed circuit board 110. For example, the electronic devices 120 may be integrated circuits, resistors, capacitors, memory modules or graphics modules. The outer surface 112 defines a first plane of the printed circuit board 110. In other embodiments, the electronic devices 120 may be coupled to the surface opposite to the outer surface 112. In yet still other embodiments, the electronic devices 120 are coupled to outer surface 112 and the surface opposite the outer surface 112.

In at least some embodiments, the printed circuit board 110 comprises a void 130 at any suitable location within the printed circuit board 110. For example, the void 130 may be located within the boundary of the printed circuit board 110, or the void 130 may be located along the boundary of the printed circuit board 110. The void 130 defines an aperture 135 through the outer surface 112 of the printed circuit board 110. In other embodiments, the printed circuit board 110 may comprise any number of voids 130, and the voids 130 may define an aperture through surface opposite to the outer surface 112. Likewise, the void 130 is shown as rectangular, but any form such as a square, a circle, or an oval may be equivalently used.

FIG. 2B illustrates a partial cross-sectional view taken along the line 2B of FIG. 2A. In particular, FIG. 2B illustrates the printed circuit board 110 comprising a plurality of layers including at least one conductive layer 140 and at least one insulative layer 142. For example, the conductive layer 140 comprises a conductive material such as copper formed into electrical traces, and the insulative layer 142 comprises an insulative laminate material such as Flame Retardant 4 (FR-4). The conductive layers 140 and the insulative layers 142 of the printed circuit board 110 may be in any order; however, in the exemplary embodiment, FIG. 2B illustrates the layers as alternating between a conductive layer 140 and an insulative layer 142. Also in the exemplary embodiments, a conductive layer 140 defines the outer surface 112 of the printed circuit board 110. In some embodiments, the conductive layer 140 may define a plurality of electrical traces that form the outer surface 112 of the printed circuit board 110.

The void 130 defines the aperture 135 through the outer surface 112 of the printed circuit board 110. The void 130 has a plurality of side walls 132 and a bottom 134. Bottom 134 is substantially parallel to the outer surface 112 of the printed circuit board 110, and the bottom 134 defines a second plane of the printed circuit board 110. In the exemplary embodiment, the surface of the bottom 134 of the void 130 is defined by a conductive layer 140 of the printed circuit board 110, and the side walls 132 are at least partially defined by an insulative layer 142. In other embodiments, the bottom 134 may be defined by an insulative layer 142 of the printed circuit board 110, and the side walls 132 may be defined completely by the insulative layer 142 or the conductive layer 140. In at least some embodiments, an electronic device 120 is coupled to the bottom 134 within the void 130. In the exemplary embodiments of FIG. 2B, the electronic device 120 is a small electronic device such as a resister (e.g., a termination resistor or a resistor in a 0402 chip package), a capacitor (e.g., a decoupling capacitor), or a filter (e.g., a power filter). Moreover, illustrative void 130 comprises only one electronic device 120, but any number of electronic devices 120 may be coupled to the bottom 134 of the void 130.

Continuing with the exemplary embodiment, the distance between the outer surface 112 and the bottom 134 of the void 130, measured along a line perpendicular to the outer surface 112, is greater than the electronic device 120 coupled to the bottom 134. Stated otherwise, the distance ‘D1’ of the void 120 is greater than the height ‘D2’ of the electronic device 120. Consider, for purpose of explanation, that the electronic 120 coupled to the bottom 134 is a resistor in a 0402 chip package. The height ‘D2’ of a resistor in a 0402 chip package ranges from 0.3 millimeters to 0.4 millimeters, thus in the exemplary embodiments, the distance ‘D2’ of the void 130 is at least greater than 0.3 millimeters. In alternative embodiments, if a plurality of electronic devices 120 are coupled to the bottom 134 within the void 130, then the distance ‘D1’ is greater than the largest height ‘D2’ among the plurality of electronic devices 120 within the void 130.

FIG. 3 illustrates, also in cross section, alternative embodiments of the printed circuit board 110. In particular, FIG. 3 illustrates the printed circuit board 110 with a plurality of layers including at least one conductive layer 140 and at least one insulative layer 142. The printed circuit board 110 has void 130 that defines an aperture 135 through the outer surface 112. An electronic device 120 is coupled to the bottom 134 of the void 130, and an electronic device 150 is coupled (e.g., by soldering) to the outer surface 112 of the printed circuit board 110. For example, the electronic device 150 may be any electronic device such as a memory module, or a graphics module. In other embodiments, the electronic device 150 may be a printed circuit board coupled to the outer surface 112 of the printed circuit board 110. The electronic device 150 at least partially occludes the aperture 135 defined by the void 130. In other embodiments, the electronic device 150 completely occludes the aperture 135 defined by the void 130. In yet still other embodiment, any number of electronic devices 150 may be coupled to outer surface 112 and at least partially occlude the aperture 135, and any number of electronic devices 120 may be coupled to the bottom 134.

In at least some embodiments, the electronic device 150 and the electronic device 120 coupled to bottom 134 of the void 130 are associated with each other. Consider, for purpose of explanation, that the electronic device 150 is a graphics module. The electronic device 120 may be an electronic device (e.g., a resistor or a capacitor) associated with the graphics module. Likewise, coupling the electronic device 150 to the outer surface 112 and coupling the electronic device 120 to the bottom 134 of the void 130 enables to couple electronic devices to the printed circuit board where the clearance between the printed circuit board and the top surface of the chassis is relatively small.

In at least some embodiments, the void 130 may be formed by removing a selected number of layers of printed circuit board 110. For example, the selected number of layers may be removed by etching away the selected number of layers or by a milling process to cut out the selected number of layers. In alternative embodiments, a selected number of layers with an aperture are laminated with layers without an aperture to form a void 130 in the printed circuit board 110. The selected number may be based on the height of the electrical devices that may be coupled to the bottom 134 of the void 130.

The above discussion is meant to be illustrative of the principles and various embodiments of the present invention. Numerous variations and modifications will become apparent to those skilled in the art once the above disclosure is fully appreciated. For example, the mobile computing system may be any mobile computing system such as a mobile telephone, a personal digital assistant (PDA), a camera or any other system that comprises a printed circuit board. Moreover, the mobile computing system 100 may comprise only a first chassis including a user interface, such as a touch screen, a pointer device, a keyboard. It is intended that the following claims be interpreted to embrace all such variations and modifications.

What is claimed is:

1. A system comprising:
a printed circuit board that comprises at least one conductive layer and at least one insulative layer, an outer surface of the printed circuit board defines a first plane;
a void within the printed circuit board, the void defines an aperture through the outer surface, the void has at least one side wall at least partially defined by the insulative layer, and the void has a bottom that defines a second plane substantially parallel to the first plane;
a first electronic device coupled to the printed circuit board within the void; and
a second electronic device coupled to the outer surface, the second electronic device at least partially occludes the aperture.

2. The system as defined in claim 1 wherein the bottom of the void is defined by a conductive layer of the printed circuit board.

3. The system as defined in claim 1 wherein a distance between the first plane and the second plane, measured along a line perpendicular to the first plane, is greater than the first electronic device.

4. The system as defined in claim 1 wherein the first electronic device comprises at least one selected from the group consisting of: resister; capacitor; and power filter.

5. The system as defined in claim 1 wherein the second electronic device is at least one selected from the group consisting of: a memory module; and a graphics module.

6. The system as defined in claim 1 wherein the conductive layer is copper.

7. The system as defined in claim 1 wherein the insulative layer is an insulative laminate material.

8. A system comprising:
a printed circuit board mounted within a chassis of a electronic device, the printed circuit board comprising:
at least one conductive layer and at least one insulative layer, an outer surface of the printed circuit board defines a first plane;
a void within the printed circuit board, the void defines an aperture through the outer surface, the void has at least one side wall at least partially defined by the insulative layer, and the void has a bottom that defines a second plane substantially parallel to the first plane;
a first electronic device coupled to the printed circuit board within the void; and
a second electronic device coupled to the outer surface, the second electronic device at least partially occludes the aperture.

9. The system as defined in claim 8 wherein the bottom of the void is defined by a conductive layer of the printed circuit board.

10. The system as defined in claim 8 wherein a distance between the first plane and the second plane, measured along a line perpendicular to the first plane, is greater than the first electronic device.

11. The system as defined in claim 8 wherein the conductive layer is copper and the insulative layer is an insulative laminate material.

12. A printed circuit board comprising:
a conductive layer and an insulative layer, the printed circuit board has an outer surface that defines a first plane;
the conductive layer defines a plurality of electrical traces on the outer surface;
a void within the printed circuit board, the void defines an aperture through the outer surface, the void has at least one side wall at least partially defined by the insulative layer, and the void has a bottom that defines a second plane substantially parallel to the first plane;
wherein a distance between the first plane and the second plane, measured along a line perpendicular to the first plane, is greater than a first electronic device coupled to the printed circuit board within the void.

13. The printed circuit board as defined in claim 12 wherein the bottom of the void is defined by a conductive layer of the printed circuit board.

14. The printed circuit board as defined in claim 12 wherein the printed circuit board further comprises a second electronic device coupled to the outer surface, the second electronic device at least partially occludes the aperture.

15. The printed circuit board as defined in claim 12 wherein the first electronic device comprises at least one selected from the group consisting of: resister; capacitor; and power filter.
